(19) United States
(12) Patent Application Publication
(10) Pub. No.: US 2025/0324823 A1
(43) Pub. Date: Oct. 16, 2025

(54) OPTOELECTRONIC DEVICE AND METHOD FOR MANUFACTURING AN OPTOELECTRONIC DEVICE

(71) Applicant: ams-OSRAM International GmbH, Regensburg (DE)

(72) Inventors: Christoph Klemp, Regensburg (DE); Andreas Biebersdorf, Regensburg (DE)

(21) Appl. No.: 18/865,635

(22) PCT Filed: May 16, 2022
(86) PCT No.: PCT/EP2022/063219

§ 371 Date: Nov. 13, 2024

(51) Int. Cl. H10H 20/816; H10H 20/01; H10H 20/82

(52) U.S. Cl. CPC H10H 20/816; H10H 20/011; H10H 20/82

(57) ABSTRACT

In an embodiment an optoelectronic device includes an epitaxially grown functional layer stack having a first layer, an active region arranged on the first layer, a second layer arranged on the active region and a third layer arranged on the second layer, the third layer having a higher concentration of the dopant of the second conductivity type than the second layer and an electrically conductive contact layer arranged on the third layer, wherein the functional layer stack is laterally limited by side surfaces of the functional layer stack and includes a central region along a center line of the functional layer stack, wherein the central region is spaced from the side surfaces, wherein a current path from the electrically conductive contact layer through the third layer to the second layer is limited to the central region, and wherein the third layer includes at least one intersection and the at least one intersection divides the third layer into at least a first region and a second region separated from the first region, the first region being limited to the central region.

### CROSS-REFERENCE TO RELATED APPLICATIONS

This patent application is a national phase filing under section 371 of PCT/EP2022/063219, filed May 16, 2022, which is incorporated herein by reference in its entirety.

### TECHNICAL FIELD

The present invention concerns an optoelectronic device and a method for manufacturing an optoelectronic device.

### BACKGROUND

Optoelectronic devices also referred to as light emitting diodes or LEDs require a supply of energy for illumination. The charge carriers introduced in an active zone of the optoelectronic device recombine under the emission of light.

A known problem for light emitting diodes, in particular very small LEDs like μ-LEDs, whose size lies in the area or less than 1000 μm² and can go down to about 10 μm², is however to efficiently generate and outcouple light. On the one hand impurities caused by the manufacturing process alongside surfaces of the optoelectronic devices can lead to (efficiency-) losses by non-radiative recombination of the charge carriers. On the other hand, a great part of the internally produced light can be trapped within the structure of the LED, as only a small share of the internally produced light can be outcoupled from the LED via direct emission from the active zone or internal reflections. The trapped light must then be decoupled from the LED for example by means of suitable outcoupling structures.

### SUMMARY

Embodiments provide an optoelectronic device. Further embodiments provide a method for manufacturing a correspondingly improved.

Embodiments provide a current confinement for an epitaxially grown functional semiconductor layer stack such that a carrier flow within the layer stack is centered to a central region of the functional layer stack. By this the carrier density alongside surfaces of the layer stack is reduced and impurities along the side faces have no or less significant influence on (efficiency-) losses by non-radiative recombination of the carriers. The functional layer stack and/or an electrically conductive contact layer arranged on the functional layer stack is therefore modified/configured to form a current path from the electrically conductive contact layer through the layer stack only in a central region of the layer stack. To additionally provide an improved outcoupling of light generated in the layer stack, several possibilities of outcoupling structures on a surface of the layer stack facing the conductive contact layer are proposed.

According to one aspect, an epitaxially grown functional layer stack is provided with an electrically conductive contact layer arranged on the functional layer stack together forming an optoelectronic device. The functional layer stack comprises a first layer with a dopant of a first conductivity type, an active region, a second layer with a dopant of a second conductivity type and a third layer with the dopant of the second conductivity type. The functional layer stack is laterally limited by side surfaces of the functional layer stack and the functional layer stack comprises a central region along a center line of the functional layer stack, wherein the centerline extends in a growth direction of the functional layer stack. The central region is defined in such that it is spaced from the side surfaces of the functional layer stack thus forming a “true” central region of the functional layer stack forming only a subregion of the functional layer stack. The third layer has a higher concentration of the dopant of the second conductivity type than the second layer and acts like a current spreading layer, but its current spreading functionality is limited to the central region of the functional layer stack. This is as the functional layer stack is modified/configured such that a current path extending from the electrically conductive contact layer through the third layer to the second layer is limited to the central region.

The functional layer stack comprises in particular a layer stack of epitaxially grown layers with an active region arranged between the first and the second layer. The first layer can for example be a p-doped layer and the second layer can be a n-doped layer. In this case the third layer can be a highly n-doped top layer of the functional layer stack to form an electrical contact with the electrically conductive contact layer (metal, TCO, etc.) applied on the functional layer stack. A high doping of the third layer in general implements good lateral current spreading into the functional layer stack. In order to implement a current confinement to the central region of the layer stack, a structuring of the electrically conductive contact layer may thus not be sufficient as lateral current spreading may still happen within the third layer. This is why the highly doped n-epi top layer is to be a) removed in an area outside the central region, or b) discontinuous/disconnected to form an electrically separated central region to suppress a lateral current spreading within the third layer.

The optoelectronic device is, for example, a radiation-emitting optoelectronic semiconductor chip. For example, the semiconductor chip may be a light emitting diode (LED) chip or a laser chip. The optoelectronic semiconductor chip may generate light during operation. In particular, it is possible that the optoelectronic semiconductor chip generates light in the spectral range from UV radiation to light in the infrared range, in particular visible light. Alternatively, it is possible that the optoelectronic semiconductor chip is a radiation-detecting semiconductor chip, for example a photodiode.

The optoelectronic device may for example comprise edge lengths of less than 100 μm, or less than 40 μm, and in particular less than 10 μm. The optoelectronic semiconductor chip can thus for example be a μLED (LED for light emitting device, μLED for micro-LED) or a μLED-chip. For such small optoelectronic devices a current confinement to reduce (efficiency-) losses by non-radiative recombination of charge carriers due to impurities alongside surfaces of the device is not known so far. The proposed principle provides however a solution to the problem.

In some aspects, the third layer is limited to the central region to provide a current confinement to the central region of the layer stack. The third layer can in particular be removed in an area outside the central region to suppress a lateral current spreading into the removed area of the third layer compared to a full third layer.

In some aspects, the third layer comprises at least one intersection, wherein the at least one intersection divides the third layer into at least a first and a second region separated from each other. The first and the second region are within the third region in particular electrically isolated from each other. The first region is limited to the central region providing a current confinement to the central region of the layer stack.

In some aspects, the electrically conductive contact layer electrically contacts the third layer only in the central region. The electrically conductive contact layer may thereby for example be limited to the central region of the functional layer stack or may extend beyond the central region but electrically contacts the third layer only in the central region. In some aspects, the electrically conductive contact layer is arranged on the third layer only in the central region and is thus limited to the central region of the functional layer stack.

In some aspects, the optoelectronic device and in particular the functional layer stack further comprises a p-type dopant, such as for example Zn (Zinc) deposited in an edge region of the active region, in particular in an area outside the central region, causing a quantum well intermixing (QWI) thereof. The efficiency of for example very small InGaAlP optoelectronic devices can thereby further be improved. Such QWI in particular is preferred in an outside the central region to further intensify the effect already created by the confinement. The QWI enlarges the band gap of the quantum wells in this outer area close to the side surfaces of the layer stack, so that the charge carriers in the quantum wells can no longer reach the side surfaces close to the quantum wells, thus further increasing the efficiency of such very small LEDs.

To additionally provide an improved outcoupling of light generated in the layer stack, several possibilities of outcoupling structures on a surface of the layer stack facing the conductive contact layer are proposed. By using an outcoupling structure as proposed in the following an enhanced light extraction of the light generated in the active zone can be provided even for small optoelectronic devices such as LEDs, in particular μ-LEDs, whose size lies in the area or less than 1000 μm² and can go down to about 10 μm².

In some aspects, the third layer, or the third layer and the second layer, comprises a first surface structuring on a surface facing the electrically conductive contact layer with a plurality of protrusions and trenches, the first surface structuring serving as an outcoupling structure on the third layer to enhance the outcoupling efficiency of light being generated within the optoelectronic device. The protrusions and trenches of the first surface structuring can thereby be homogeneously distributed but can also have an inhomogeneous/random distribution. The protrusions of the first surface structuring can all be of the same height, or their height can vary for all or for only several of the protrusions.

In some aspects, protrusions of the first surface structuring in the central region are higher than protrusions of the first surface structuring outside the central region. By this the electrically conductive contact layer, for example extending over the whole third layer, can contact the third layer and in particular the protrusions of the first surface structuring of the third layer only in the central region. Higher in this context may in particular be understood in such that the top level of the protrusions outside the central region are above the top level of the protrusions within the central region.

In some aspects, protrusions of the first surface structuring at least in the central region have a planarized surface facing the electrically conductive contact layer. In particular protrusions contacting the electrically conductive contact layer have a planarized surface facing the electrically conductive contact layer. Such a planarized surface can for example result of a planarization of the protrusions to provide a contact surface for the have a planarized surface facing the electrically conductive contact layer.

In some aspects, protrusions of the first surface structuring electrically contact the electrically conductive contact layer at least in the central region.

In some aspects, the second layer comprises a second surface structuring on a surface facing the electrically conductive contact layer with a plurality of protrusions and trenches, in particular in an area outside the central region. The second surface structuring can in particular be arranged in an area outside the central region in which the third layer is removed serving as an outcoupling structure on the second layer to enhance the outcoupling efficiency of light being generated within the optoelectronic device. The protrusions and trenches of the second surface structuring can thereby be homogeneously distributed but can also have an inhomogeneous/random distribution. The protrusions of the second surface structuring can all be of the same height, or their height can vary for all or for only several of the protrusions.

The first and/or the second surface structuring can correspond to a roughening of the third and/or second layer and can be chosen/generated with regard to the desired need and desired outcoupling characteristics.

In some aspects, the optoelectronic device further comprises a planarization layer arranged on the third and/or second layer. The planarization layer in particular fills the at least one intersection and/or the trenches of the first and/or second surface structuring and/or covers the first and/or second surface structuring at least in an area outside the central region. The planarization layer is in particular of a transparent material to allow light being generated within the optoelectronic device to transmit trough the planarization layer. In case of the planarization layer covering the first and/or second surface structuring, the planarization layer in addition has a low refractive index to further improve or at least not to counteract the outcoupling improved outcoupling efficiency due to the first and/or second surface structuring.

In some aspects, the planarization layer is of an electrically isolating material. By this an area of the third and optionally second layer outside the central region can be electrically isolated from the electrically conductive contact layer, in particular in case of the electrically conductive contact layer extending over the whole functional layer stack.

In some aspects, the planarization layer covers the functional layer stack over the whole functional layer stack whereas in some aspects the planarization layer covers the functional layer stack only in the central region. In the latter case the planarization layer can for example also be of a transparent conductive material such as indium tin oxide (ITO).

In some aspects, the central region is limited to half of the distance between two opposing side surfaces of the functional layer stack. The central region can in particular be a subregion of the functional layer stack extending along a centre line of the functional layer stack, wherein the central region is compared to the rest of the functional layer stack smaller and in particular less than half of the functional layer stack.

In some aspects, the distance of the central region to an adjacent side surface is in the order of the mean free path of mobile carriers of the functional layer stack. By this, a recombination of charge carriers close to the side surfaces can be suppressed. In some aspects, the distance between the central region and an adjacent side surface is between 500 nm and 2500 nm, between 500 nm and 2000 nm, or between 500 nm and 1500 nm.

In some aspects, the first layer and/or the second layer and/or the third layer comprises a base material selected from the group consisting of:
GaN;
AlGaN;
AlGaInP;
AlGaInN; and
AlGaP.

Other material may also be used. The first layer and/or the second layer in particular comprise epitaxially grown layers.

Some other aspects concern a method for manufacturing at least one optoelectronic device. In a first step a functional layer stack is provided comprising a first layer with a dopant of a first conductivity type, an active region arranged on the first layer, a second layer with a dopant of a second conductivity type arranged on the active region, and a third layer with the dopant of the second conductivity type arranged on the second layer, the third layer having a higher concentration of the dopant of the second conductivity type than the second layer. The functional layer stack is laterally limited by side surfaces of the functional layer stack and comprises a central region along a center line of the functional layer stack, wherein the central region is spaced from the side surfaces forming a subregion of the functional layer stack. Then an electrically conductive contact layer is provided on the third layer such that a current path from the electrically conductive contact layer through the third layer to the second layer is limited to the central region.

In some aspects, the method further comprises a removal or a thinning of the third layer in an area outside the central region or the method further comprises a creation of at least one intersection in the third layer such that the at least one intersection divides the third layer into at least a first and a second region separated from each other, the first region being limited to the central region. The removal or creation of the intersection can be done after the functional layer stack has been grown on for example a wafer and after the functional layer stack has been removed and transferred from the wafer to a final destination. The removal or creation of the intersection can comprise an etching process and/or photolithographic processes.

In some aspects, the method further comprises a roughening of a surface of the third layer facing the electrically conductive contact layer to create a first surface structuring with a plurality of protrusions and trenches.

In some aspects, the method further comprises a roughening of a surface of the second layer facing the electrically conductive contact layer, in particular in an area outside the central region where the third layer has been removed, to create a second surface structuring with a plurality of protrusions and trenches.

The steps of removing or a thinning the third layer, creating at least one intersection in the third layer, roughening a surface of the third layer, and/or roughening a surface of the second layer can for example be done in one and the same process. This can for example be achieved by using loading effects with dry etching processes. Thereby large structures are etched faster/deeper than small structures, such that the creation of a roughening and the creation of for example the at least one intersection can be started at the same time resulting in the respective structures.

The roughening of the second and/or third layer can comprise etching processes and/or photolithographic processes. The roughening can for example be done over the whole surface of the third layer facing the electrically conductive contact layer or can be done only in the central region, or can be done only next to the central region.

The roughening can for example be done e.g. by using “Kugelfischen/natural lithography” from OSRAM thin film products or by photolithographic processes followed by etching processes. To avoid far field features due to regular surface patterns (photonic grid), it can be beneficial to arrange the structures/protrusions randomly. The etching could be done by etching “holes” into the surface of the third and/or second layer, or by having remaining areas (etching everything but defined areas). It has been found that etching resulting in shaped/angled sidewalls (e.g. pyramids vs. pillars) are beneficial, as well as etching everything but defined areas is beneficial. It has further been found that structure sizes with a CD (critical dimension, e.g. diameter of top surface) below 1 μm are beneficial.

The roughening of the third layer can for example be done after at least a portion of the electrically conductive contact layer has been provided on the third layer, in particular on the third layer in the central region. For example, AuGe can be deposited on the third layer in the central region before a roughening using photolithographic and etching processes. The roughening process can be done that way, that parts of the metal are remaining on top of resulting protrusions in the third layer (only on the tops of remaining pyramids AuGe is present and contacts the third layer). In a following step and to complete the electrically conductive contact layer the AuGe portions can be connected by a subsequent deposition of a conductive material such as for example a transparent conducting oxide (TCO).

The step of providing the electrically conductive contact layer can comprise applying thin metal layers and/or a layer of a TCO onto the third layer and in particular onto protrusions of the first surface structuring.

In some aspects, the method further comprises a filling of the at least one intersection and/or the trenches of the first and/or second surface structuring with a filling material, for example an electrically isolating filling material. The filling can be for example comprise a deposition of the filling material onto the third and/or second layer. The filling material can form a planarization layer that covers the functional layer stack over the whole functional layer stack or that covers the functional layer stack only in the central region. The planarization layer can for example also be of a transparent conductive material such as for example indium tin oxide (ITO).

The filling can be for example done with any transparent material. For the choice of the material, the following aspects may besides other be considered:
low refractive index; the higher the refractive index, the less efficient the roughening increases the outcoupling efficiency.
electrically isolating materials electrically isolate the electrically conductive contact layer and the third layer in desired areas.
conductive materials can have the advantages:
   1) the electrical contact is done easily and does not need further processing steps.
   2) If a pick method using electrostatic forces is used, and polarizable surface is advantageous for the picking process and conductive materials are always good polarizable.

In some aspects, the method further comprises a planarization of protrusions of the first surface structuring at least in the central region as well as a planarization of the filling material if present. The planarization can help to provide a planar surface for providing the electrically conductive contact layer on.

Advantages of an optoelectronic device according to some aspects of the invention are a higher internal efficiency (IQE) due to reduced losses at side surfaces of the optoelectronic device. Furthermore, the light extraction efficiency (LEE) can be increased by an appropriate removal of the third layer, or a shaping of the emission surface by for example creating a surface structuring on the emission surface of the optoelectronic device. Shaping the emission surface can besides increasing the light extraction efficiency lead to a higher level of Lambertian far field distribution. At the same time the optoelectronic device according to some aspects of the invention can still be provided with a good pick and place ability.

### BRIEF DESCRIPTION OF THE DRAWINGS

In the following, embodiments of the invention will be explained in more detail with reference to the accompanying drawings.

FIG. 1 shows a cross sectional view of an optoelectronic device;

FIG. 2A and 2B show each a cross sectional view of an optoelectronic device according to some aspects of the invention; and

FIG. 3A to 7C show each a cross sectional view of a further embodiment of an optoelectronic

### DETAILED DESCRIPTION OF ILLUSTRATIVE EMBODIMENTS

The present disclosure will now be described more fully hereinafter with reference to the accompanying drawings, in which exemplary embodiments of the disclosure are shown. The disclosure may, however, be embodied in many different forms and should not be construed as limited to the embodiments set forth herein; rather, these embodiments are provided for thoroughness and completeness. Like reference characters refer to like elements throughout the description. The drawings are not necessarily to scale and certain features may be exaggerated in order to better illustrate and explain the exemplary embodiments of the present disclosure.

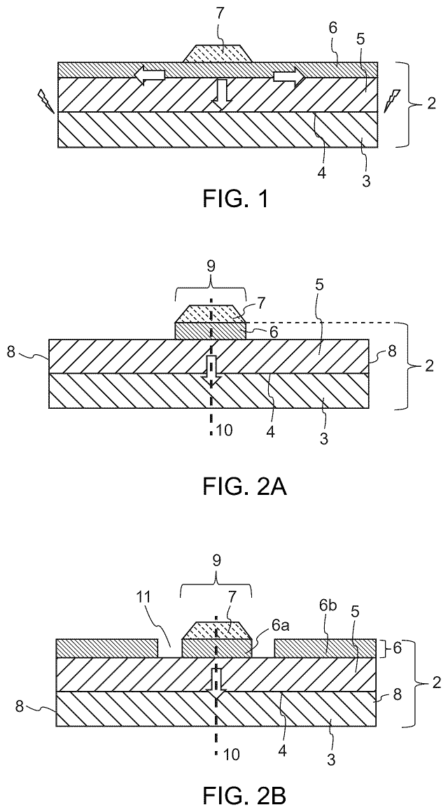

FIG. 1 shows a cross-sectional view of an optoelectronic device comprising a layer stack 2 with a first layer 3 with a dopant of a first conductivity type, an active region 4 arranged on the first layer 3, a second layer 5 with a dopant of a second conductivity type arranged on the active region 4, and a third layer 6 with the dopant of the second conductivity type arranged on the second layer 5, the third layer 6 having a higher concentration of the dopant of the second conductivity type than the second layer 5. Further to this, an electrically conductive contact layer 7 is arranged on the third layer 6. By electrically connecting the optoelectronic device, charge carriers (indicated by the tree arrows) are due to the high doping of the third layer 6 spread throughout the third layer and introduced in the active region 4 of the optoelectronic device and recombine under the emission of light. However, charge carriers recombining alongside surfaces of the functional layer stack may due to impurities of the material recombine without an emission of light leading to non-radiative losses (indicated by the two lightning bolts). These non-radiative losses reduce the internal efficiency (IQE) of the optoelectronic device and are thus unwanted, in particular for the optoelectronic device being particularly small.

The inventors however found that implementing a current confinement for the functional layer stack, such that a carrier flow within the layer stack is centered to a central region of the functional layer stack can help to reduce these non-radiative losses. By a current confinement the carrier density alongside surfaces 8 of the layer stack is reduced and impurities along the side faces have no or less significant influence on (efficiency-) losses by non-radiative recombination of the carriers. The functional layer stack and/or an electrically conductive contact layer arranged on the functional layer stack is therefore modified/configured to form a current path from the electrically conductive contact layer through the layer stack only in a central region of the layer stack as shown in several embodiment in FIGS. 2A to 7C. Some of the embodiments shown in the Figures additionally provide an improved outcoupling of light generated in the layer stack, by providing an outcoupling structure on a surface of the layer stack facing the conductive contact layer.

FIG. 2A shows an optoelectronic device 1 in a cross-sectional view. The optoelectronic device 1 comprises a layer stack 2 with a first layer 3 with a dopant of a first conductivity type, an active region 4 arranged on the first layer 3, a second layer 5 with a dopant of a second conductivity type arranged on the active region 4, and a third layer 6 with the dopant of the second conductivity type arranged on the second layer 5, the third layer 6 having a higher concentration of the dopant of the second conductivity type than the second layer 5. Further to this, an electrically conductive contact layer 7 is arranged on the third layer 6. The functional layer stack 2 is laterally limited by side surfaces 8 of the functional layer stack 2 and comprises a central region 9 along a center line 10 of the functional layer stack 2. The central region 9 is spaced from the side surfaces 8 forming a subregion of the layer stack extending throughout the layer stack along the center line 10 of the functional layer stack. To provide a current confinement the third layer 6 is modified in such that a current path from the electrically conductive contact layer 7 through the third layer 6 to the second layer 5 is limited to the central region 9. An area of the third layer 6 outside the central region has been removed or its height has been reduced in an area outside the central region for this purpose, in order to guide a current introduced into the electrically conductive contact layer 7 to the central region and not spread it throughout an entire third layer extending over the entire functional layer stack 2. The removal of an area of the third layer 6 outside the central region can in addition also lead to an at least partial removal of the second layer 5 reducing its height in an area outside the central region.

FIG. 2B shows an alternative embodiment of the optoelectronic device 1. To provide a current confinement the third layer 6 has not been removed entirely in areas outside the central region but intersections 11 have been introduced to divide the third layer 6 into a first region 6a and a second region 6b. The first region 6a is thereby limited to the central region 9 and the electrically conductive contact layer 7 contacts the third layer only in the first region/central region. A current path from the electrically conductive contact layer 7 through the third layer 6 to the second layer 5 is thus limited to the central region 9 in order to guide a current introduced to the electrically conductive contact layer 7 to the central region and not spread it throughout the entire third layer 6.

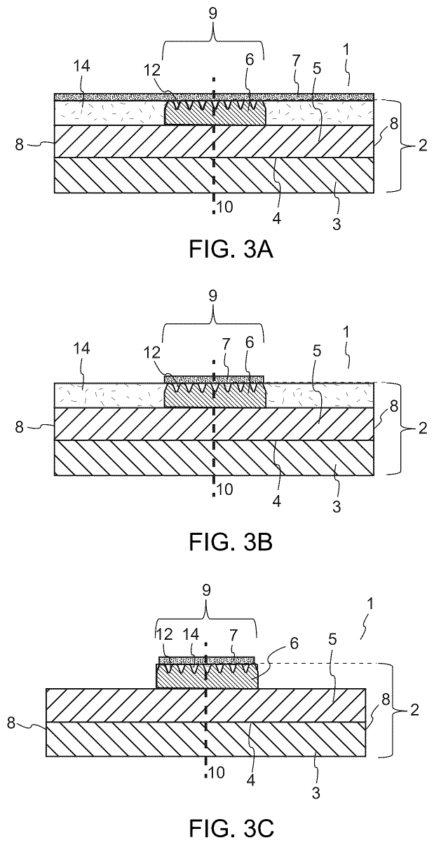

FIGS. 3A to 3C show embodiments in which the area of the third layer 6 outside the central region 9 has been removed to provide a current confinement. In addition a first surface structuring 12 is provided on the third layer 6 on a surface facing the electrically conductive contact layer 7 comprising a plurality of protrusions and trenches. The first surface structuring can be to improve the outcoupling efficiency of the optoelectronic device 1.

As shown in FIG. 3A and 3B a planarization layer 14 is arranged on the layer stack 2 replacing areas which have been removed from the third layer 6 outside the central region and to provide the first surface structuring 12. The planarization layer 14 is in particular of a transparent material, which in case of FIGS. 3A and 3B could in addition be an electrically isolating material to not counteract the current confinement generated by removing the third layer outside the central region. The electrically conductive contact layer 7 contacts the protrusions of the first surface structuring while the trenches are filled by the planarization layer. For better contacting the protrusions can be planarized to provide a good contact surface for the electrically conductive contact layer 7.

The electrically conductive contact layer 7 can extend over the entire functional layer stack (see FIG. 3A) or can be limited to the central region 9 (see FIG. 3B). In particular in case of the electrically conductive contact layer 7 extending over the entire functional layer stack it may be of a transparent conductive material to allow the light being generated in the functional layer stack to emerge from the optoelectronic device 1.

As shown in FIG. 3C, the planarization layer can also only cover the first surface structuring filling the trenches of the first structuring 12. In this case the planarization layer can also be of an electrically conductive material such as for example a TCO, to provide a good current spreading into the third layer within the central region 9.

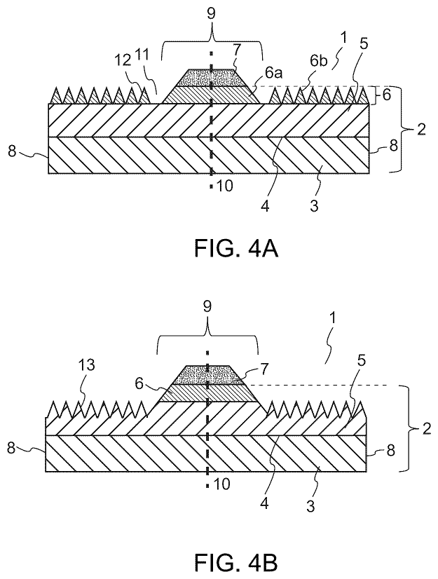

FIGS. 4A and 4B show embodiments of the optoelectronic device 1 without a planarization layer. The optoelectronic device of FIG. 4A and in particular the third layer 6 of the optoelectronic device 1 comprises in addition to the embodiment shown in FIG. 2B a first surface structuring on the second region 6b of the third layer 6 on a surface facing the electrically conductive contact layer 7. The first surface structuring comprises a plurality of protrusions and trenches and can be to improve the outcoupling efficiency of the optoelectronic device 1.

The optoelectronic device of FIG. 4B and in particular the second layer 6 of the optoelectronic device 1 outside the central region comprises in addition to the embodiment shown in FIG. 2A a second surface structuring on a surface facing the electrically conductive contact layer 7. The second surface structuring comprises a plurality of protrusions and trenches and can be to improve the outcoupling efficiency of the optoelectronic device 1.

In a not shown embodiment, the third layer 6 of the optoelectronic device 1 comprises as for example shown in FIG. 4A a first surface structuring on the second region 6b of the third layer 6 on a surface facing the electrically conductive contact layer 7, wherein the first surface structuring extends down into the second layer 5 as well. The first surface structuring thus comprises a plurality of protrusions and trenches, wherein the trenches can at least partly be arranged in the second layer 5 and can be to improve the outcoupling efficiency of the optoelectronic device 1.

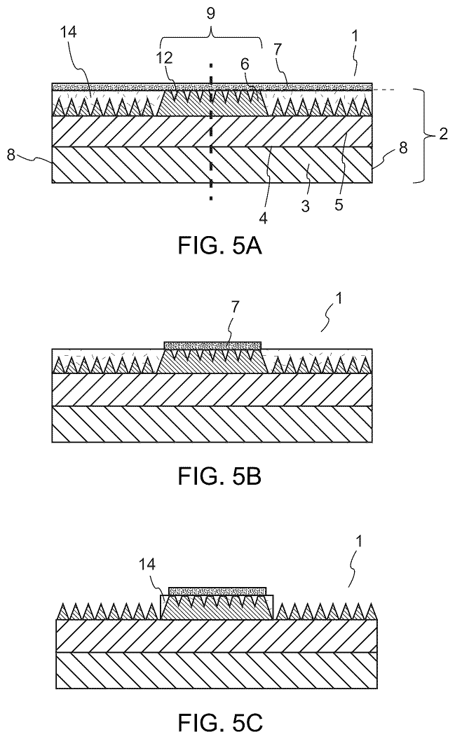

FIGS. 5A to 5C show embodiments of the optoelectronic device 1 which in addition to the embodiment shown in FIG. 4A comprise a planarization layer 14 and in which the first surface structuring 12 also extends on a surface of the third layer 6 in the central region 9. Protrusions of the first surface structuring 12 are thereby higher in the central region 9 than in an area outside the central region to provide a contacting surface for the electrically conductive contact layer 7 and to provide a current confinement to the central region 9 when arranging the third layer with an electrically conductive contact layer 7 extending over the entire functional layer stack as shown in FIG. 5A.

In addition, and to provide the current confinement the third layer may comprise at least one intersection dividing the third layer in at least a first and a second region, where the first region is in contact to the electrically conductive contact layer 7 and forms the current path from the electrically conductive contact layer 7 to the second layer.

As shown in FIG. 5A and 5B the planarization layer 14 is arranged on the layer stack 2 replacing areas which have been removed from the third layer 6 outside the central region and to provide the first surface structuring 12. The planarization layer 14 is in particular of a transparent material, which in case of FIGS. 5A and 5B should in addition be an electrically isolating material to not counteract the current confinement generated by removing the third layer outside the central region. The electrically conductive contact layer 7 contacts the protrusions of the first surface structuring while the trenches are filled by the planarization layer. For better contacting the protrusions can be planarized to provide a good contact surface for the electrically conductive contact layer 7.

The electrically conductive contact layer 7 can extend over the entire functional layer stack (see FIG. 5A) or can be limited to the central region 9 (see FIG. 5B). In particular in case of the electrically conductive contact layer 7 extending over the entire functional layer stack it may be of a transparent conductive material to allow the light being generated in the functional layer stack to emerge from the optoelectronic device 1.

As shown in FIG. 5C, the planarization layer 14 can also only cover the first surface structuring 12 filling the trenches of the first structuring 12 in the central region 9. In this case the planarization layer can also be of an electrically conductive material such as for example a TCO, to provide a good current spreading into the third layer within the central region 9.

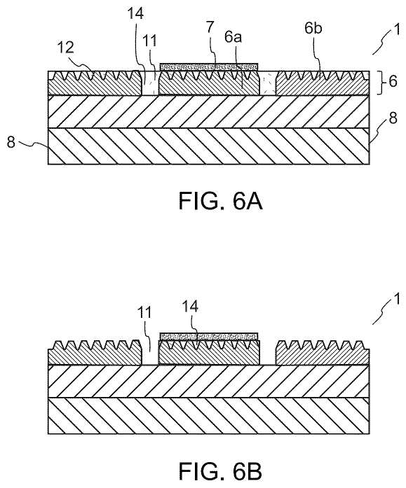

FIGS. 6A and 6B show embodiments of the optoelectronic device 1 in which compared to the embodiment shown in FIG. 5A and 5B protrusions of the first surface structuring 12 substantially have the same height throughout the first surface structuring 12. To provide a current confinement to the central region 9, the third layer comprises intersections 11 dividing the third layer into a first region 6a and a second region 6b, where the first region is limited to the central region and contacts the electrically conductive contact layer 7 also being limited to the central region 9.

As shown in FIG. 6A, the planarization layer 14 is arranged on the layer stack 2 replacing areas which have been removed from the third layer 6 in in the intersections and in the trenches of the first surface structuring. The planarization layer 14 can, as shown in FIG. 6B, only cover the first surface structuring 12 filling the trenches of the first structuring 12 in the central region 9. In this case the planarization layer can also be of an electrically conductive material such as for example a TCO, to provide a good current spreading into the third layer within the central region 9.

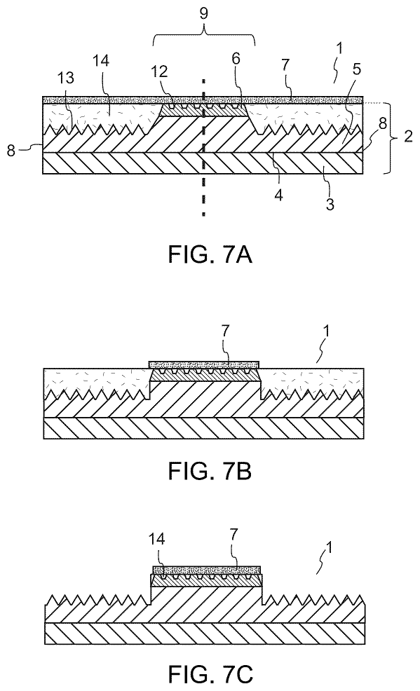

FIGS. 7A to 7C show a further development of the embodiment of FIG. 4B, according to which not only the second layer comprises the second surface structuring 13, but the third layer 6 also comprises a first surface structuring provided on the third layer 6 on a surface facing the electrically conductive contact layer 7 comprising a plurality of protrusions and trenches. The first surface structuring can be to improve the outcoupling efficiency of the optoelectronic device 1.

As shown in FIG. 7A and 7B a planarization layer 14 is arranged on the layer stack 2 replacing areas which have been removed from the third layer 6 outside the central region and to provide the first surface structuring 12 as well as in the trenches of the second surface structuring 13. The planarization layer 14 is in particular of a transparent material, which in case of FIGS. 3A and 3B should in addition be an electrically isolating material to not counteract the current confinement generated by removing the third layer outside the central region. The electrically conductive contact layer 7 contacts the protrusions of the first surface structuring while the trenches are filled by the planarization layer. For better contacting the protrusions can be planarized to provide a good contact surface for the electrically conductive contact layer 7.

The electrically conductive contact layer 7 can extend over the entire functional layer stack (see FIG. 7A) or can be limited to the central region 9 (see FIG. 7B). In particular in case of the electrically conductive contact layer 7 extending over the entire functional layer stack it may be of a transparent conductive material to allow the light being generated in the functional layer stack to emerge from the optoelectronic device 1.

As shown in FIG. 7C, the planarization layer can also only cover the first surface structuring filling the trenches of the first structuring 12. In this case the planarization layer can also be of an electrically conductive material such as for example a TCO, to provide a good current spreading into the third layer within the central region 9.

1.-20. (canceled)

21. An optoelectronic device comprising:
an epitaxially grown functional layer stack comprising:
a first layer with a dopant of a first conductivity type;
an active region arranged on the first layer;
a second layer with a dopant of a second conductivity type arranged on the active region; and
a third layer with the dopant of the second conductivity type arranged on the second layer, the third layer having a higher concentration of the dopant of the second conductivity type than the second layer; and
an electrically conductive contact layer arranged on the third layer,
wherein the functional layer stack is laterally limited by side surfaces of the functional layer stack and comprises a central region along a center line of the functional layer stack,
wherein the central region is spaced from the side surfaces,
wherein a current path from the electrically conductive contact layer through the third layer to the second layer is limited to the central region, and
wherein the third layer comprises at least one intersection and the at least one intersection divides the third layer into at least a first region and a second region separated from the first region, the first region being limited to the central region.

22. The optoelectronic device according to claim 21, wherein the electrically conductive contact layer electrically contacts the third layer only in the central region and/or is arranged on the third layer only in the central region.

23. The optoelectronic device according to claim 21, wherein the third layer, or the third layer and the second layer, comprises a first surface structuring on a surface facing the electrically conductive contact layer with a plurality of protrusions and trenches.

24. The optoelectronic device according to claim 23, wherein protrusions of the first surface structuring in the central region are higher than protrusions of the first surface structuring outside the central region.

25. The optoelectronic device according to claim 23, wherein protrusions of the first surface structuring at least in the central region have a planarized surface facing the electrically conductive contact layer.

26. The optoelectronic device according to claim 23, wherein protrusions of the first surface structuring electrically contact the electrically conductive contact layer in the central region.

27. The optoelectronic device according to claim 21, wherein the second layer comprises a second surface structuring on a surface facing the electrically conductive contact layer with a plurality of protrusions and trenches in an area outside the central region.

28. The optoelectronic device according to claim 21, further comprising a planarization layer arranged on the third and/or second layer, wherein the planarization layer fills the at least one intersection and/or trenches of first and/or second surface structuring.

29. The optoelectronic device according to claim 28, wherein the planarization layer is of an electrically isolating material.

30. The optoelectronic device according to claim 21, wherein the central region is limited to half of a distance between two opposing side surfaces of the functional layer stack.

31. The optoelectronic device according to claim 21, wherein the first layer and/or the second layer and/or the third layer comprises a base material selected from the group consisting of GaN, AlGaN, AlGaInP, AlGaInN and AlGaP.

32. A method for manufacturing at least one optoelectronic device, the method comprising:
providing a functional layer stack comprising:
a first layer with a dopant of a first conductivity type;
an active region arranged on the first layer;
a second layer with a dopant of a second conductivity type arranged on the active region; and
a third layer with the dopant of the second conductivity type arranged on the second layer, the third layer having a higher concentration of the dopant of the second conductivity type than the second layer,
wherein the functional layer stack is laterally limited by side surfaces of the functional layer stack and comprises a central region along a center line of the functional layer stack, and
wherein the central region is spaced from the side surfaces;
providing an electrically conductive contact layer on the third layer such that a current path from the electrically conductive contact layer through the third layer to the second layer is limited to the central region; and
creating at least one intersection in the third layer such that the at least one intersection divides the third layer into at least a first region and a second region separated from the first region, the first region being limited to the central region.

33. The method according to claim 32, further comprising removing the third layer in an area outside the central region.

34. The method according to claim 32, further comprising roughening a surface of the third layer facing the electrically conductive contact layer to create a first surface structuring with a plurality of protrusions and trenches.

35. The method according to claim 34, further comprising planarizing protrusions of the first surface structuring at least in the central region.

36. The method according to claim 32, further comprising roughening a surface of the second layer facing the electrically conductive contact layer in an area outside the central region to create a second surface structuring with a plurality of protrusions and trenches.

37. The method according to claim 32, further comprising filling the at least one intersection and/or trenches of first and/or second surface structuring with an electrically isolating filling material.
